(19) United States
(12) Patent Application Publication
(10) Pub. No.: US 2002/0177274 A1
(43) Pub. Date: Nov. 28, 2002

(54) Method for forming flash memory cell

(75) Inventors: Ping-Yi Chang, Kaohsiung (TW); Wan-Yi Liu, Kaohsiung City (TW); Shu-Li Wu, Nan-Tao City (TW)

Correspondence Address: LOWE HAUPTMAN GILMAN AND BERNER, LLP, 1700 DIAGONAL ROAD, SUITE 300 /310, ALEXANDRIA, VA, 22314, US

(73) Assignee: MACRONIX INTERNATIONAL CO., LTD.

(21) Appl. No.: 09/862,495

(22) Filed: May 23, 2001

(51) Int. Cl. H01L 21/336

(52) U.S. Cl. 438/257

(57) ABSTRACT

The present invention provides a method for forming a flash memory cell and comprises following steps. First, a substrate is provided. Then, a first polysilicon layer and a nitride layer are sequentially formed on the substrate. Next, a portion of the nitride layer and the polysilicon layer are removed to form a plurality of holes to expose the substrate. Following, an isolation dielectric is formed in those holes, wherein the isolation dielectric is gibbous in a sidewall of those holes and higher than the first polysilicon layer. Then, the nitride layer on the first polysilicon layer is removed. Last, a second polysilicon layer is conformally formed on the first polysilicon layer and the isolation dielectric.

### BACKGROUND OF THE INVENTION

1. Field of the Invention

The present invention generally relates to a method for forming a flash memory cell, and more particularly relates to a method for forming a flash memory cell by using a sputtering process.

2. Description of the Prior Art

Flash memory is the most potential memory in the semiconductor industry. Flash memory have been broadly applied to replicatively access date but not disappear as power breaking down, such as the film of digital camera or the basic input-output system of a mother board, because flash memory has the advantages of electrically erasable and programmable mechanisms. Flash memory can simultaneously proceed the erase and the program mechanisms to all flash memory cells in the whole memory's array. Accordingly, how to advance the performance and reduce the cost of the flash memory becomes an important subject.

In the conventional method for forming a flash memory cell, the isolation oxide is formed and then a planarization process is performed, such as a chemical mechanism polishing (CMP) process. In the process steps, the CMP process is difficult controlled and the common disadvantages is dishing or erosion on the surface. Hence, there are many solutions to overcome the disadvantages of the CMP process. Moreover, it is more and more important to integrate the processes and to increase the efficiency of the flash memory.

### SUMMARY OF THE INVENTION

An object of the invention is to provide a method for forming a flash memory cell by using a sputtering process to form isolation oxide.

Another object of the invention is to provide a method for forming a flash memory cell, which can effectively increase the storage of electrical charges.

In order to achieve previous objects, the present invention provides a method for forming a flash memory cell and comprises following steps. First, a substrate is provided. Then, a first polysilicon layer and a nitride layer are sequentially formed on the substrate. Next, the nitride layer and the polysilicon layer are etched to form a plurality of holes to expose the substrate. Following, an isolation dielectric is formed in those holes, wherein the isolation dielectric is gibbous in a sidewall of those holes and higher than the first polysilicon layer. Then, the nitride layer on the first polysilicon layer is removed. Last, a second polysilicon layer is conformally formed on the first polysilicon layer and the isolation dielectric.

### BRIEF DESCRIPTION OF THE DRAWINGS

The foregoing aspects and many of the accompanying advantages of this invention will become more readily appreciated as the same becomes better understood by reference to the following detailed description, when taken in conjunction with the accompanying drawings, wherein:

FIG. 1A to FIG. 1F are the schematic representations of structures at various stages during the formulation of a flash memory cell, in accordance with the present invention.

### DESCRIPTION OF THE PREFERRED EMBODIMENT

The semiconductor devices of the present invention are applicable to a broad rang of semiconductor devices and can be fabricated from a variety of semiconductor materials. The following description discusses several presently preferred embodiments of the semiconductor devices of the present invention as implemented in silicon substrates, since the majority of currently available semiconductor devices are fabricated in silicon substrates and the most commonly encountered applications of the present invention will involve silicon substrates. Nevertheless, the present invention may also be advantageously employed in gallium arsenide, germanium, and other semiconductor materials. Accordingly, application of the present invention is not intended to be limited to those devices fabricated in silicon semiconductor materials, but will include those devices fabricated in one or more of the available semiconductor materials.

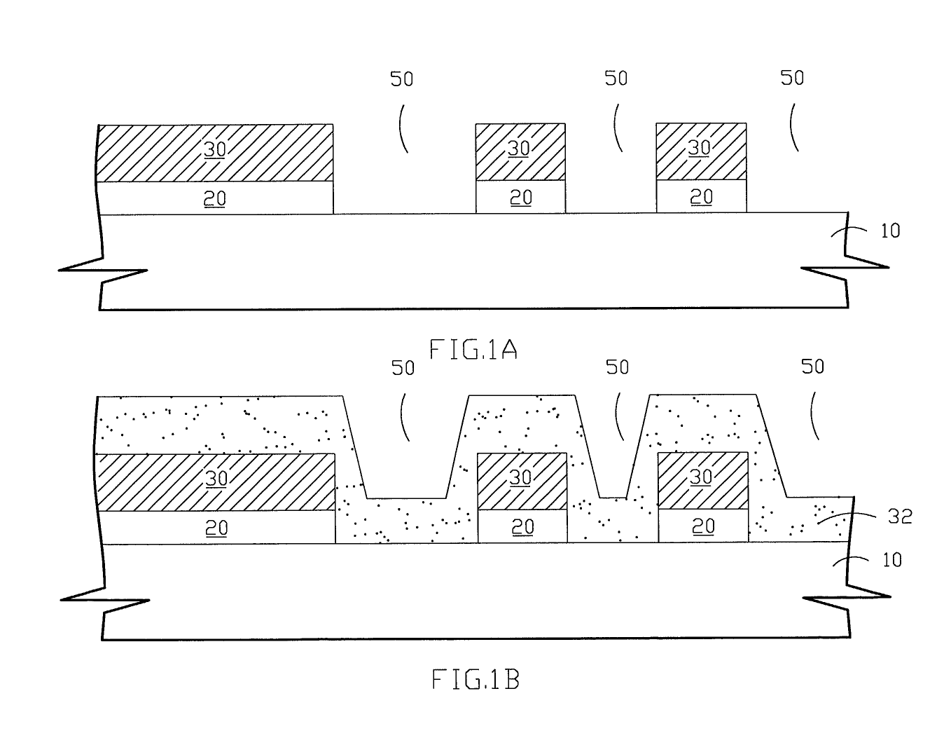

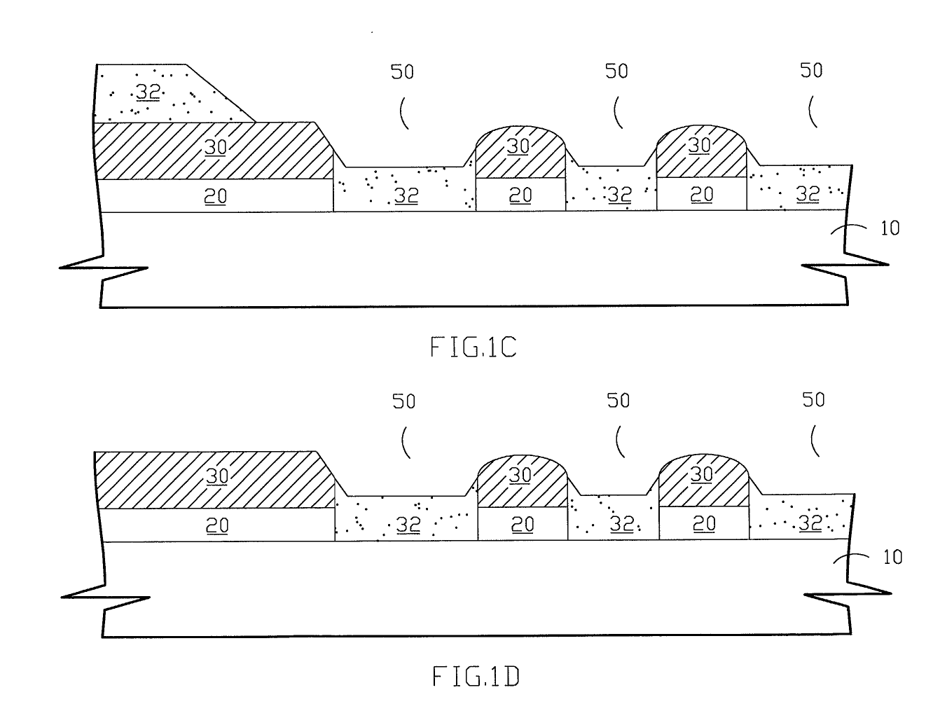

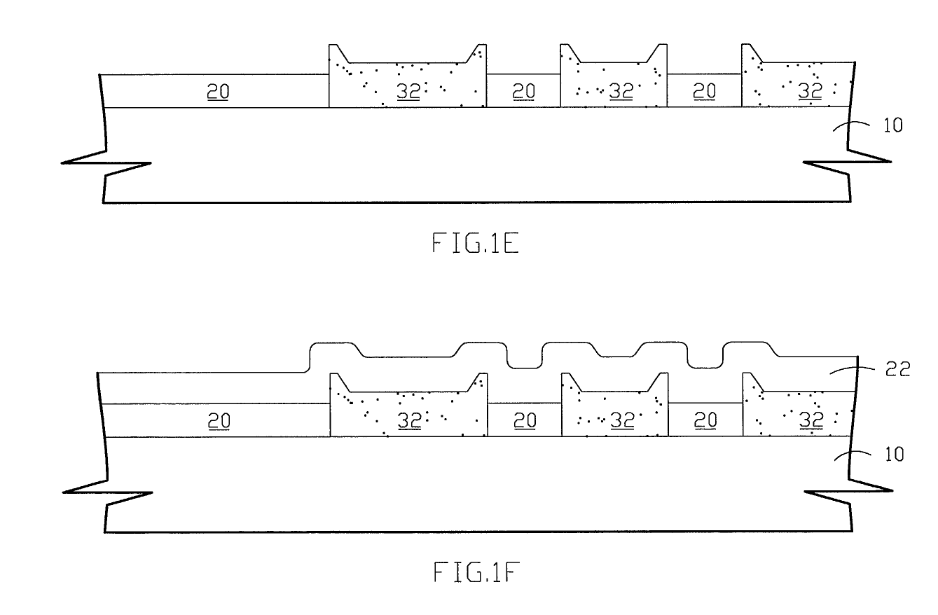

Referring to FIG. 1A, a substrate 10 is provided. Then, a first polysiliocn 20 layer is deposited on the substrate 10. Next, a nitride layer 30 is deposited on the first polysilicon layer 20. The nitride layer 30 is made of silicon nitride. Following, a lithography process is performed to remove a portion of the nitride layer 30 and the first polysilicon layer 20 and to form a plurality of holes 50 to expose the substrate 10. After the lithography process, the first polysilicon layer 20 is patterned.

Referring to FIG. 1B, a dielectric layer 32 is conformally deposited on the nitride layer 30 and those holes 50. The dielectric layer 32 is made of oxide and is formed by a chemical vapor deposition method, such as a high-density plasma enhanced chemical vapor deposition method. The thickness of the dielectric layer 32 is thicker than the thickness of the first polysilicon layer 20. The dielectric layer 32 is used as the isolation oxide in a flash memory cell.

Referring to FIG. 1C, a sputtering process is performed to remove a portion of the dielectric layer 32 to expose a portion of the nitride layer 30. Then, the remained dielectric layer 32 in those holes 50 is gibbous in a sidewall of those holes.

Referring to FIG. 1D, then, the remained dielectric layer 30 on the nitride layer 30 is removed. Removing the remained dielectric layer 32 on the nitride layer 30 comprises following steps. First, a mask is formed to cover the remained dielectric layer 32 in those holes 50. Then, the remained dielectric layer 32 on the nitride layer 30 is removed by using a wet etching process. Last, the mask is removed.

Next, referring to FIG. 1E, the nitride layer 30 is stripped by using an etching process. The remained dielectric layer 32 in those holes 50 is gibbous in a surface of the first polysilicon layer 20 and thicker than the first polysilicon layer 20. Last, referring to FIG. 1F, a second polysilicon layer 22 is conformally deposited on the first polysilicon layer 20 and the dielectric layer 32.

In the present invention, a sputtering process is performed in the formation of the isolation oxide. The sputtering process is to remove a portion of the dielectric layer to form the isolation oxide and then a wet etching process is performed to remove the excess dielectric layer. In the current method, the chemical mechanism polishing process is commonly used for forming the isolation oxide in a flash memory cell. There are many disadvantages of the chemical mechanism polishing process. One is that the chemical mechanism polishing process is difficult to control and causes the dishing surface. Therefore, there are many solutions to overcome the disadvantage of the chemical mechanism polishing process. However, the use of the chemical mechanism polishing process needs more complicated steps. The present invention uses the sputtering process and can easily overcome the disadvantage of the chemical mechanism polishing process. Furthermore, in the present invention, the isolation oxide is gibbous the surface of the first polysilicon layer, so the isolation oxide can increase the surface of the second polysilicon layer which is conformally deposited on the first polysilicon layer and the isolation oxide. The surface of the second polysilicon layer is increased and the ability of the storage of electric charges of the second polysilicon layer is also improved, so the performance of the flash memory cell is improved at the same time.

To sum up the foregoing, the present invention uses a sputtering process to form the isolation and to overcome the disadvantage of the chemical mechanism polishing process. Moreover, the shape of the isolation oxide can effectively improve the performance of the flash memory cell. The present invention can easily perform by using the visible equipment and processes.

Of course, it is to be understood that the invention need not be limited to these disclosed embodiments. Various modification and similar changes are still possible within the spirit of this invention. In this way, the scope of this invention should be defined by the appended claims.

What is claimed is:

1. A method for forming a flash memory cell, said method comprising:
providing a substrate;
forming a first polysilicon layer on said substrate;
forming a nitride layer on said first polysilicon layer;
removing a portion of said nitride layer and said polysilicon layer to form a plurality of holes to expose said substrate;
forming an isolation dielectric in said holes, wherein said isolation dielectric is gibbous in a sidewall of said holes and higher than said first polysilicon layer;
removing said nitride layer on said first polysilicon layer; and
conformally forming a second polysilicon layer on said first polysilicon layer and said isolation dielectric.

2. The method according to claim 1, wherein said polysilicon layer is formed by using a depositing process.

3. The method according to claim 1, wherein said nitride layer is formed by using a depositing process.

4. The method according to claim 1, wherein said nitride layer is made of silicon nitride.

5. The method according to claim 1, wherein the step of forming said isaolation dielectric in said holes comprises following steps:
conformlly depositing a dielectric layer on said nitride layer and said substrate;
using a sputtering process to remove a portion of said dielectric layer and to expose a portion of said nitride layer; and
removing said dielectric layer on said nitride layer.

6. The method according to claim 5, wherein said dielectric layer is formed by using a chemical vapor depositing process.

7. The method according to claim 5, wherein said dielectric layer is formed by using a high-density plasma enhanced chemical vapor deposition (HDPCVD) process.

8. The method according to claim 5, wherein the step of removing said dielectric layer on said nitride layer comprises following steps:
forming a mask to cover remained said dielectric layer in said holes;
using a wet etching process to remove said dielectric layer on said nitride layer; and
removing said mask.

9. A method for forming a flash memory cell, said method comprising:
providing a substrate;
forming a first polysilicon layer on said substrate;
forming a nitride layer on said first polysilicon layer;
removing a portion of said nitride layer and said polysilicon layer to form a plurality of holes to expose said substrate;
conformlly depositing a dielectric layer on said nitride layer and said substrate;
using a sputtering process to remove a portion of said dielectric layer and to expose a portion of said nitride layer;
removing said dielectric layer on said nitride layer, wherein remained said dielectric layer in said holes is gibbous in a sidewall of said holes and higher than said first polysilicon layer;
removing said nitride layer on said first polysilicon layer; and
conformally forming a second polysilicon layer on said first polysilicon layer and said isolation dielectric.

10. The method according to claim 9, wherein said polysilicon layer is formed by using a depositing process.

11. The method according to claim 9, wherein said nitride layer is formed by using a depositing process.

12. The method according to claim 9, wherein said nitride layer is made of silicon nitride.

13. The method according to claim 9, wherein said dielectric layer is formed by using a chemical vapor depositing process.

14. The method according to claim 9, wherein said dielectric layer is formed by using a high-density plasma enhanced chemical vapor deposition (HDPCVD) process.

15. The method according to claim 9, wherein the step of removing said dielectric layer on said nitride layer comprises following steps:
forming a mask to cover remained said dielectric layer in said holes;
using a wet etching process to remove said dielectric layer on said nitride layer; and
removing said mask.
